(19) United States
(12) Patent Application Publication
(10) Pub. No.: US 2017/0077252 A1
(43) Pub. Date: Mar. 16, 2017

(54) SEMICONDUCTOR DEVICE

(71) Applicant: KABUSHIKI KAISHA TOSHIBA, Tokyo (JP)

(72) Inventors: Takuma SUZUKI, Himeji Hyogo (JP); Junichi UEHARA, Himeji Hyogo (JP)

(21) Appl. No.: 15/062,203

(22) Filed: Mar. 7, 2016

(30) Foreign Application Priority Data
Sep. 14, 2015 (JP) 2015-180374

(51) Int. Cl. H01L 29/45; H01L 21/04; H01L 29/78; H01L 29/739; H01L 29/16; H01L 29/10

(52) U.S. Cl. CPC H01L 29/45; H01L 29/1608; H01L 29/1095; H01L 29/7802; H01L 29/7395; H01L 21/0485

(57) ABSTRACT

A semiconductor device includes a silicon carbide layer having first and second surfaces, a first insulating film on the first surface, a first electrode on the first insulating film, a first silicon carbide region of a first conductivity type in the silicon carbide layer, a second silicon carbide region of a second conductivity type in the first silicon carbide region, a third silicon carbide region of the first conductivity type in the second silicon carbide region, a second electrode on the second surface, which contains metal, silicon, and carbon, and a third electrode in contact with the third silicon carbide region, which contains metal, silicon, and carbon, and has a carbon concentration higher than a carbon concentration of the second electrode.

### CROSS-REFERENCE TO RELATED APPLICATION

This application is based upon and claims the benefit of priority from Japanese Patent Application No. 2015-180374, filed Sep. 14, 2015, the entire contents of which are incorporated herein by reference.

### FIELD

Embodiments described herein relate generally to a semiconductor device.

### BACKGROUND

Silicon carbide (SiC) is expected to be used as the material for next-generation semiconductor devices. As compared to silicon (Si), SiC has characteristics in which the bandgap is approximately three times, breakdown field strength is approximately 10 times, and thermal conductivity is approximately three times. For this reason, by using SiC, it is possible to realize a semiconductor device which has low loss and can perform a high temperature operation.

However, a semiconductor device which uses SiC suffers from a decrease in reliability due to separation of an electrode film.

### DESCRIPTION OF THE DRAWINGS

FIG. 1 is a schematic sectional view of a semiconductor device according to a first embodiment.

FIG. 2 is a flowchart of a manufacturing method of the semiconductor device according to the first embodiment.

FIGS. 3-9 are each a cross sectional view illustrating the method of manufacturing the semiconductor device according to the first embodiment.

FIGS. 10A to 10D are views illustrating effects of the first embodiment.

FIG. 11 is a cross sectional view of a semiconductor device according to a second embodiment.

FIG. 12 is a cross sectional view illustrating a method of manufacturing the semiconductor device according to the second embodiment.

FIG. 13 is a cross sectional view of a semiconductor device according to a third embodiment.

FIG. 14 is a cross sectional view of a semiconductor device according to a fourth embodiment.

### DETAILED DESCRIPTION

Embodiments provide a semiconductor device which improves reliability reducing the likelihood of separation of an electrode film.

In general, according to one embodiment, a semiconductor device includes a silicon carbide layer having a first surface, and a second surface on a side of the silicon carbide layer opposite to the first surface, a first insulating film on the first surface, a first electrode on the first insulating film, a first silicon carbide region of a first conductivity type in the silicon carbide layer, a second silicon carbide region of a second conductivity type in the first silicon carbide region, a portion of which is at the first surface, a third silicon carbide region of the first conductivity type in the second silicon carbide region, a portion of which is at the first surface, a second electrode on the second surface, which contains metal, silicon, and carbon, and a third electrode in contact with the third silicon carbide region, which contains metal, silicon, and carbon, and has a carbon concentration higher than a carbon concentration of the second electrode.

Hereinafter, embodiments of the disclosure will be described with reference to the drawings.

In the present disclosure, the same symbols or reference numerals will be given to the same or similar elements, and description thereof will be repeated only as needed.

Hereinafter, a case in which a first conductivity type is an n-type and a second conductivity type is a p-type will be used as an example. In addition, in the present disclosure, notation of n⁺, n and n⁻, and p⁺, p and p⁻ represents relative levels of impurity concentrations of each conductivity type. That is, n⁺-type impurity concentration is higher than n-type impurity concentration, and n⁻-type impurity concentration is lower than n-type impurity concentration. In addition, p⁺-type impurity concentration is higher than p-type impurity concentration, and p⁻-type impurity concentration is lower than p-type impurity concentration. In some cases, n⁺ and n⁻ are simply referred to as an n type, and p⁺ and p⁻ are simply referred to as a p type.

In the disclosure, in order to represent a positional relationship of components or the like, an upward direction of the drawing is referred to as “upper”, and a downward direction of the drawing is referred to as “lower”. In the disclosure, concept of “upper” and “lower” may or may not be aligned with the direction of gravity.

### First Embodiment

A semiconductor device according to the present embodiment includes a silicon carbide layer which has a first surface, and a second surface that is provided on a side opposite to the first surface; a first insulating film which is provided on the first surface; a first electrode which is provided on the first insulating film; a first silicon carbide region of a first conductivity type which is provided in the silicon carbide layer and a portion of which is provided at the first surface; a second silicon carbide region of a second conductivity type which is provided in the first silicon carbide region, and a portion of which is provided at the first surface; a third silicon carbide region of a first conductivity type which is provided in the second silicon carbide region, and a portion of which is provided at the first surface; a second electrode which is provided on the second surface and contains metal, silicon, and carbon; and a third electrode which is in contact with the third silicon carbide region, contains metal, silicon, and carbon, and has a carbon concentration higher than a carbon concentration of the second electrode.

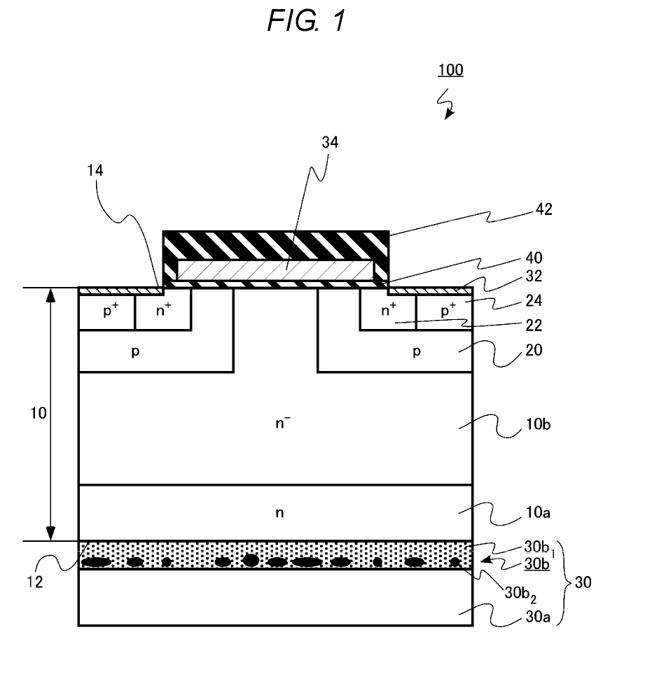

FIG. 1 is a schematic sectional view of a semiconductor device according to the present embodiment.

A semiconductor device 100 includes a silicon carbide layer 10, a first electrode 34, a second electrode 30, a third electrode 32, a first insulating film 40, and a second insulating film 42.

The silicon carbide layer 10 includes a first surface, and second surface provided on a side opposite to the first surface. The silicon carbide layer 10 includes an n-type drift region (first silicon carbide region) 10b, a p-type well region (second silicon carbide region) 20, an n-type source region (third silicon carbide region) 22, a p-type contact region (fourth silicon carbide region) 24, and an n-type drain region (fifth silicon carbide region) 10a.

The semiconductor device 100 according to the present embodiment is formed by injecting ions into the well region 20 and the source region 22, and is a double implantation metal oxide semiconductor field effect transistor (DI MOSFET).

The n-type first silicon carbide region 10b is provided in the silicon carbide layer 10, and a portion thereof is provided on a first surface 14 of the silicon carbide layer 10. The first silicon carbide region 10b functions as a drift region of the MOSFET. The first silicon carbide region 10b contains, for example, n-type impurity higher than or equal to 5×10¹⁵ cm⁻³ and lower than or equal to 5×10¹⁶ cm⁻³. The impurity concentration of the first silicon carbide region 10b is lower than impurity concentration of the fifth silicon carbide region 10a which will be described below.

The first insulating film 40 is provided on the first surface 14. The first insulating film 40 is a gate insulating film. The first insulating film 40 is, for example, a silicon oxide film or a high-k film.

The first electrode 34 is provided on the first insulating film 40. The first electrode 34 is a gate electrode. The first electrode 34 contains, for example, polycrystalline silicon in which impurity is doped.

The p-type well region 20 is provided in the first silicon carbide region 10b, and a portion thereof is provided on the first surface 14. The well region 20 functions as a channel region of the MOSFET. A depth of the well region 20 is, for example, approximately 0.6 μm. The well region 20 contains, for example, p-type impurity higher than or equal to 5×10¹⁵ cm⁻³ and lower than or equal to 1×10¹⁹ cm⁻³. The p-type impurity is, for example, aluminum (Al), boron (B), gallium (Ga), or indium (In).

The n-type source region 22 is provided in the well region 20, and a portion thereof is provided on the first surface 14. The source region 22 functions as a source of the MOSFET. A depth of the source region 22 is, for example, approximately 0.3 μm and is smaller than the well region 20. The source region 22 contains, for example, n-type impurity higher than or equal to 1×10¹⁸ cm⁻³ and lower than or equal to 1×10²¹ cm⁻³. The n-type impurity is, for example, phosphorus (P), nitride (N), arsenic (As), or antimony (Sb).

The p-type contact region 24 is provided in the well region 20, and is electrically coupled to the third electrode 32 which will be below. The contact region 24 is used to reduce a contact resistance between the well region 20 and the third electrode 32 which will be described below. A depth of the contact region 24 is, for example, approximately 0.3 μm and is smaller than the well region 20. The contact region 24 contains, for example, p-type impurity higher than or equal to 1×10¹⁸ cm⁻³ and lower than or equal to 1×10²¹ cm⁻³. The impurity concentration of the contact region 24 is higher than impurity concentration of the well region 20.

The second electrode 30 is provided on a second surface 12 of the silicon carbide layer 10. The second electrode 30 is a drain electrode. The second electrode 30 includes a first electrode layer 30a which contains a metal and silicon, and a second electrode layer 30b which contains a metal, silicon, and carbon, and is provided between the first electrode layer 30a and the silicon carbide layer 10. A thickness of the first electrode layer 30a is, for example, approximately 500 nm. A thickness of the second electrode layer 30b is, for example, approximately 100 nm.

It is preferable that the first electrode layer 30a contains metal silicide (compound of metal and silicon). It is preferable that the metal is nickel in order to reduce a contact resistance.

It is preferable that the second electrode layer 30b includes a first phase 30b₁ containing metal silicide and carbon, and a second phase 30b₂ containing carbon. It is preferable that the metal is nickel in order to reduce a contact resistance.

The third electrode 32 is provided in the source region 22 so as to come into contact with the source region 22. The third electrode 32 is electrically coupled to the third silicon carbide region 22 and the fourth silicon carbide region 24. The third electrode 32 is a source electrode. The third electrode 32 contains a metal, silicon, and carbon. Carbon concentration of the third electrode 32 is higher than carbon concentration of the second electrode 30. It is preferable that the third electrode 32 contains metal silicide. It is preferable that the metal is nickel in order to form a good Ohmic contact.

Carbon concentration of the second electrode 30 and carbon concentration of the third electrode 32 can be measured by a transmission electron microscope-energy dispersive X-ray spectroscopy (TEM-EDX). In each of the second electrode 30 and the third electrode 32, carbon concentration of the center in a thickness direction is measured inside a surface in parallel with the thickness direction, whereby carbon concentration is obtained. Spatial resolution in a case in which the carbon concentration is measured is, for example, 5 nm.

The fifth silicon carbide region 10a is provided in the silicon carbide layer 10 between the first silicon carbide region 10b and the second electrode 30. The fifth silicon carbide region 10a contains, for example, n-type impurity higher than or equal to 1×10¹⁸ cm⁻³ and lower than or equal to 1×10²⁰ cm⁻³, and is n-type 4H—SiC. 3C—SiC or 6H—SiC may also be used. The n-type impurity is, for example, nitride (N), arsenic (As), phosphorus (P), or antimony (Sb).

The second insulating film 42 is provided on an upper portion of the first insulating film 40, and on a side and an upper portion of the first electrode 34. The second insulating film 42 electrically isolates the third electrode 32 from the first electrode 34.

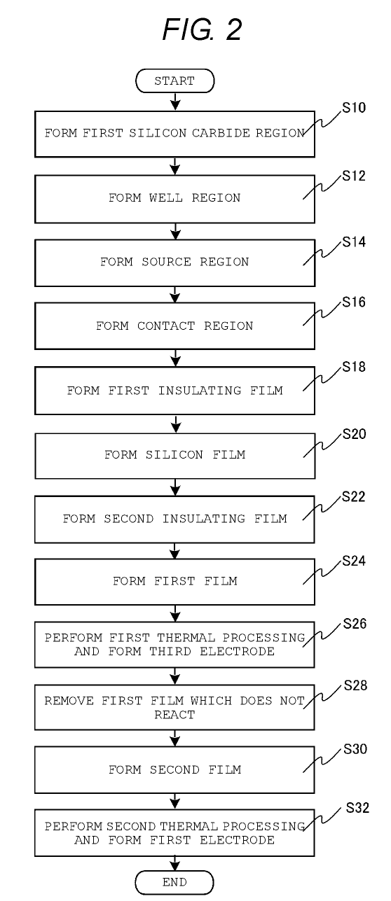

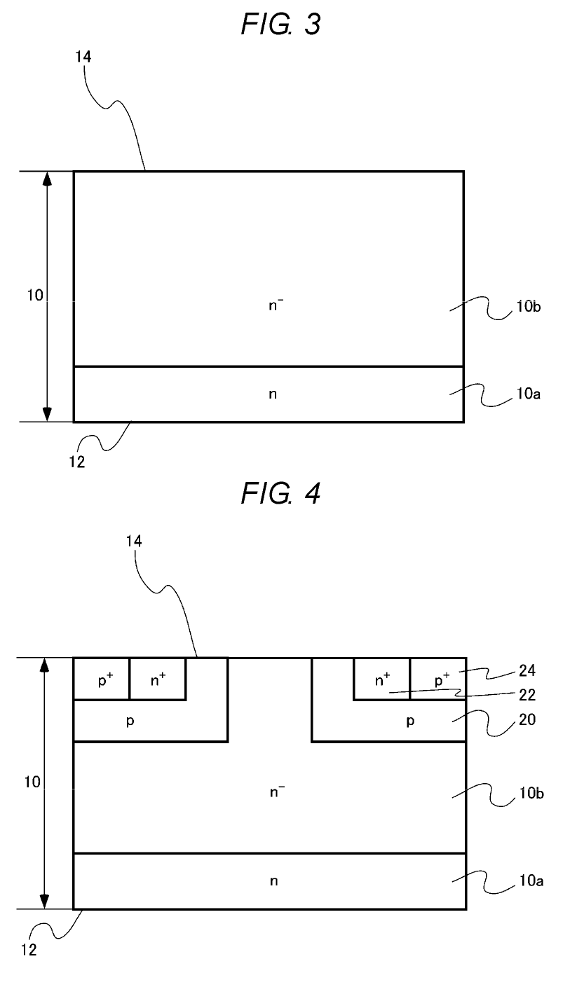

Next, a manufacturing method of the semiconductor device 100 according to the present embodiment will be described. FIG. 2 is a flowchart of the manufacturing method of the semiconductor device according to the present embodiment. FIGS. 3 to 9 are schematic sectional views of the semiconductor device in the process of the manufacturing method of the semiconductor device according to the present embodiment.

According to the manufacturing method of the semiconductor device 100 according to the present embodiment, the first silicon carbide region 10b of an n-type is formed on the fifth silicon carbide region 10a of an n-type, the p-type well region 20 is formed on the first silicon carbide region 10b so as to be exposed at the first surface 14, the n-type source region 22 is formed in the well region 20 so as to be exposed at the first surface 14, the p-type contact region 24 is formed on a side of the source region 22 on the well region 20 so as to be exposed at the first surface 14, the first insulating film 40 is formed on the first surface 14, the first electrode 34 is formed on the first insulating film 40, the second insulating film 42 is formed on the first insulating film 40 and the first electrode 34, a first film 52 is formed on the first silicon carbide region 10b, the well region 20, the source region 22, the contact region 24, the first insulating film 40, and the second insulating film 42, first thermal processing is performed, the first film 52 which does not react is removed, a second film 54 is formed on the second surface, and second thermal processing is performed.

First, as illustrated in FIG. 3, the first silicon carbide region 10b of an n-type is formed on the fifth silicon carbide region 10a of an n-type by, for example, an epitaxial method (S10). The fifth silicon carbide region 10a and the first silicon carbide region 10b make up the silicon carbide layer 10. A surface on the first silicon carbide region 10b is the first surface 14, and a surface of the fifth silicon carbide region 10a on a side opposite to the first surface 14 is the second surface 12.

Subsequently, as illustrated in FIG. 4, the well region 20 is formed on the first silicon carbide region 10b so as to be exposed at the first surface 14, by injecting, for example, Al ion. (S12).

Subsequently, the n-type source region 22 is formed in the well region 20 so as to be exposed at the first surface 14, by injecting, for example, P ion (S14). In addition, the p-type contact region 24 is formed on a side of the source region 22 on the well region 20 so as to be exposed at the first surface 14 (S16). Thereafter, thermal processing for activating the well region 20, the source region 22, and the contact region 24 is performed.

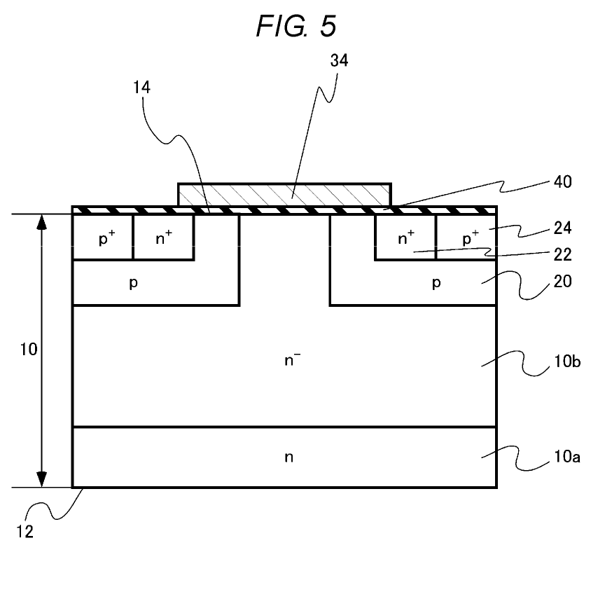

Subsequently, as illustrated in FIG. 5, the first insulating film 40 is formed on the first surface 14 by, for example, a thermal oxidation method or chemical vapor deposition (CVD) method (S18). Subsequently, the first electrode 34 containing, for example, polycrystalline silicon is formed on the first insulating film 40, and thereafter etching is performed (S20).

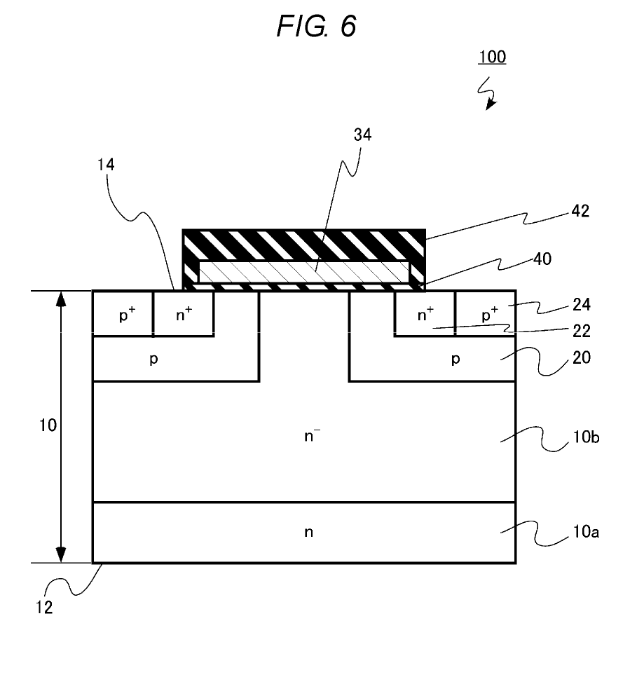

Subsequently, as illustrated in FIG. 6, the second insulating film 42 including, for example, silicon oxide film is formed on the first insulating film 40 and the first electrode 34. Subsequently, a portion of the second insulating film 42 formed on the source region 22 and on the contact region 24 are removed by, for example, etching (S22).

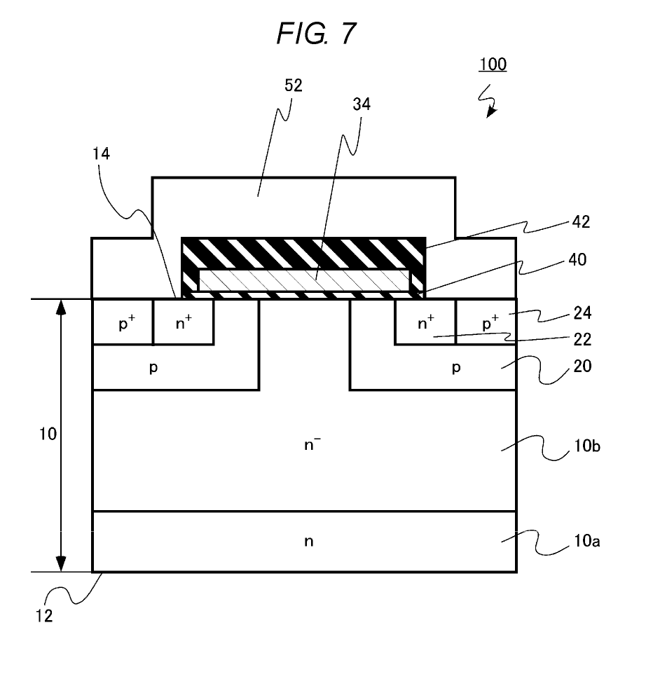

Subsequently, as illustrated in FIG. 7, the first film 52 containing, for example, nickel (Ni) is formed on the first silicon carbide region 10b, the well region 20, the source region 22, the contact region 24, the first insulating film 40, and the second insulating film 42 (S24).

Subsequently, first thermal processing is performed. Thereby, the source region 22 and the contact region 24 react with the first film 52, whereby the third electrode 32 which is a layer of a metal semiconductor compound containing nickel silicide is formed (S26).

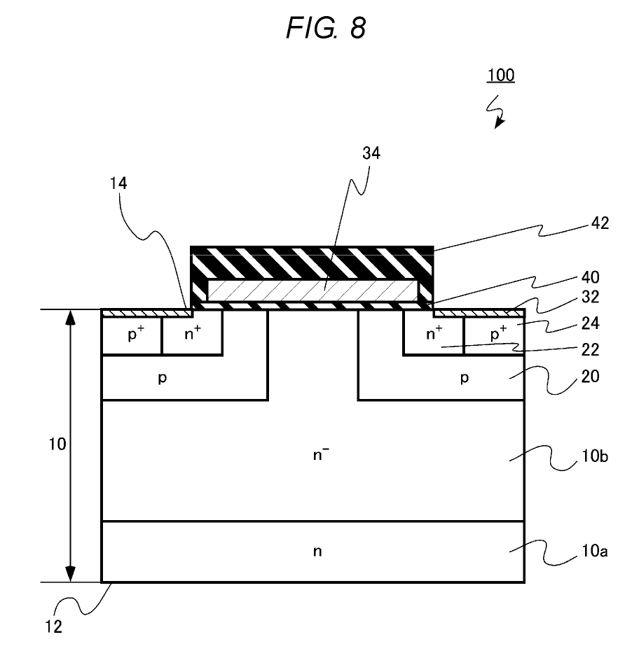

Subsequently, as illustrated in FIG. 8, the first film 52 which did not react in step S26 is removed by an acid solution or the like containing sulfuric acid (S28).

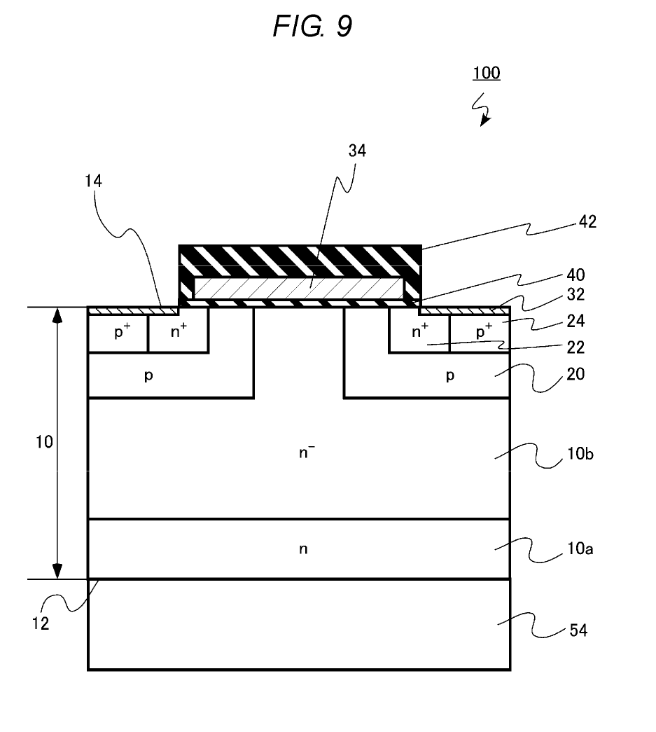

Subsequently, as illustrated in FIG. 9, the second film 54 containing NiSi is formed on the second surface, by, for example, a sputtering method (S30). It is preferable that a ratio between Ni and Si is between 2:1 and 1:3, in order to reduce a silicide reaction of the fifth silicon carbide region.

It is preferable that a thickness of the second film 54 is greater than or equal to 100 nm and smaller than or equal to 1,000 nm. If the thickness is smaller than 100 nm, reaction with the fifth silicon carbide region 10a which will be described below occurs in the entirety of the second film 54, the amount of the second phase 30b₂ being generated is increased, and a contact resistance increases. Meanwhile, if the thickness is greater than 1,000 nm, heat which is produced from the semiconductor device 100 cannot be efficiently dissipated from a heat sink or the like provided in a lower portion of the semiconductor device 100.

Subsequently, second thermal processing is performed, the second electrode 30 is formed by reacting the second film 54 with the fifth silicon carbide region 10a (S32), whereby the semiconductor device 100 illustrated in FIG. 1 is fabricated.

For example, the temperature of the second thermal processing is higher than or equal to 800° C. and lower than or equal to 1,050° C. If the temperature is lower than 800° C., the second film 54 and the fifth silicon carbide region 10a do not sufficiently react with each other, whereby the contact resistance increases. Meanwhile, if the temperature is higher than 1,050° C., the second phase 30b₂ grows too much, and separation of the film of the second electrode 30 easily occurs.

The second thermal processing is performed in an atmosphere of inert gas such as argon (Ar). In addition, time in which the second thermal processing is performed is, for example, approximately four minutes.

Now, effects of the semiconductor device 100 according to the present embodiment will be described.

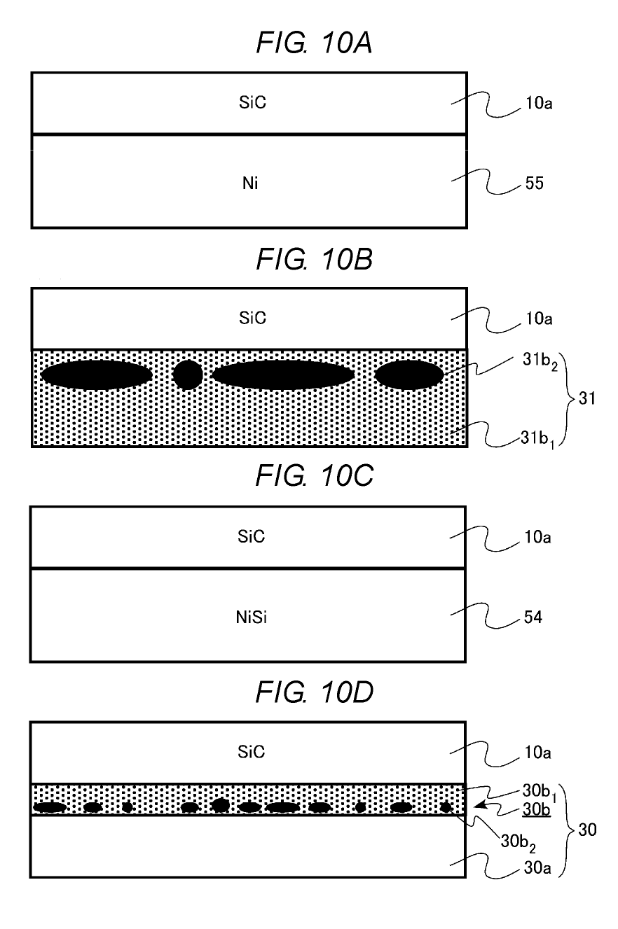

FIGS. 10A to 10D are views illustrating effects of the present embodiment. FIG. 10A is a schematic sectional view of a second film 55 and the fifth silicon carbide region 10a before thermal processing in a semiconductor device of a comparative example. FIG. 10B is a schematic sectional view of a second electrode 31 and the fifth silicon carbide region 10a after thermal processing in the semiconductor device of the comparative example. FIG. 10C is a schematic sectional view of the second film 54 and the fifth silicon carbide region 10a before the second thermal processing in the semiconductor device 100 according to the present embodiment. FIG. 10D is a schematic sectional view of the second electrode 30 and the fifth silicon carbide region 10a after the second thermal processing in the semiconductor device 100 according to the present embodiment.

In FIG. 10A, nickel (Ni) is used for the second film 55. In this case, as illustrated in FIG. 10B, the entire second film 55 reacts with the fifth silicon carbide region 10a during the thermal processing. In the second electrode 31 formed thereby, carbon (C) is diffused in Ni, and the second electrode 31 includes the first phase 31b₁ which contains Ni and C and the second phase 31b which represents agglomeration of C. In other words, an electrode layer corresponding to the first electrode layer 30a in the semiconductor device 100 illustrated in FIG. 1 cannot be formed. In addition, the second phase 31b₂ is formed on a side of the second electrode 31, which is close to the fifth silicon carbide region 10a. The second phase 31b₂ causes separation of a film of the second electrode 31.

In FIG. 10C, NiSi is used for the second film 54. In this case, as illustrated in FIG. 10D, after the second thermal processing, a first electrode layer 30a with small amount of carbon, and a second electrode layer 30b which is provided between the first electrode layer 30a and the fifth silicon carbide region 10a and includes the first phase 30b₁ and the second phase 30b₂, are formed. If the second film 54 contains Si, the amount of the fifth silicon carbide region 10a which reacts with the second film 54 is suppressed. For this reason, the amount of the second phase 30b₂ which is formed in the second electrode 30 is small. Hence, the film of the second electrode 30 is unlikely to separate.

In order to form the third electrode 32, the first film 52 which does not react is removed by an acid solution containing sulfuric acid, whereby the third electrode 32 can be simply formed. Accordingly, it is preferable to use a metal film which does not contain silicon, for example, a film which contains nickel. In this case, the amount of reaction of the source region 22 and the contact region 24 which react with the first film 52 is not suppressed, and thus the carbon concentration of the third electrode becomes higher than the carbon concentration of the second electrode. In this case, it is preferable that the carbon concentration of the third electrode is higher than or equal to 1×10¹⁸ atoms/cm³.

In addition, a thickness of the second electrode 30 is greater than a thickness of the third electrode 32, but it is preferable that film separation is prevented by increasing strength of the second electrode 30, and a contact resistance of the third electrode 32 is reduced.

As such, in the semiconductor device 100 according to the present embodiment, it is possible to provide a semiconductor device which improves reliability by decreasing the likelihood of film separation of the second electrode (drain electrode).

### Second Embodiment

A semiconductor device according to the present embodiment is different from the semiconductor device according to the first embodiment in that a fourth electrode 35 containing metal silicide functions as a gate electrode. Here, description of the contents which overlap those of the first embodiment will be omitted.

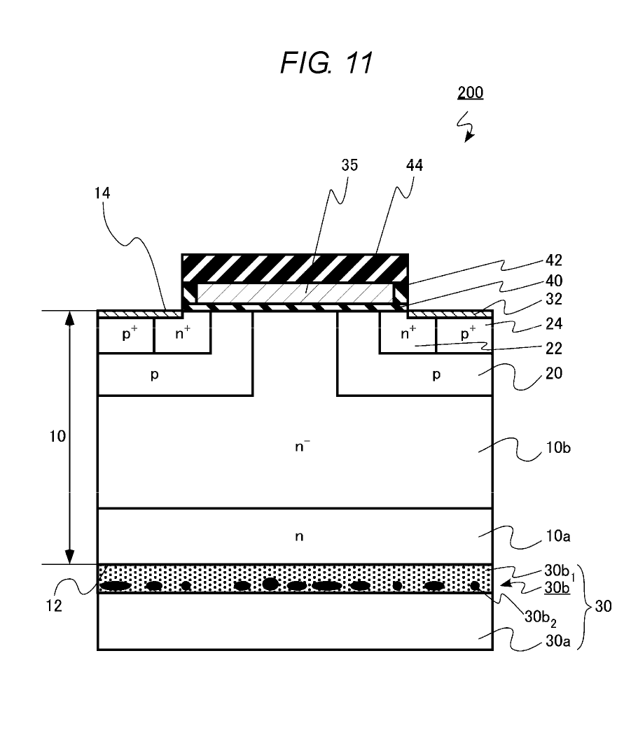

FIG. 11 is a schematic sectional view of the semiconductor device according to the present embodiment.

In the semiconductor device according to the present embodiment, the fourth electrode 35 is provided on the first insulating film 40. The second insulating film 42 is provided on a side of the fourth electrode 35 on the first insulating film 40. In addition, a third insulating film 44 is provided on the second insulating film 42 and the fourth electrode 35.

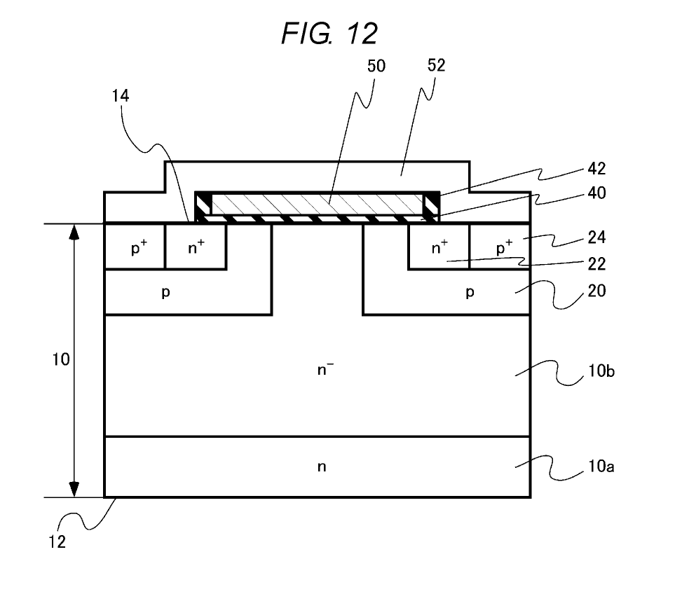

FIG. 12 is a schematic sectional view of the semiconductor device in the process of a manufacturing method of the semiconductor device according to the present embodiment. In the manufacturing method of the semiconductor device according to the present embodiment, the first film 52 is formed on a silicon film 50 formed of polycrystalline silicon, the source region 22, and the contact region 24. Thereafter, first thermal processing is performed, the silicon film 50 and the first film 52 react with each other, whereby the fourth electrode 35 which is a layer of a metal semiconductor compound containing nickel silicide is formed. In addition, the first film 52 which does not react is removed by an acid solution containing sulfuric acid, and thereafter the third insulating film 44 is formed on the second insulating film 42 and the fourth electrode 35. The other steps except for these are the same as the manufacturing method of the semiconductor device according to the first embodiment.

In a case of a gate electrode which uses polycrystalline silicon, an interface depletion layer is formed. Meanwhile, in a semiconductor device 200 according to the present embodiment, metal silicide is used for the gate electrode, and thus the interface depletion layer is not formed. For this reason, in the semiconductor device 200 according to the present embodiment, it is possible to provide a semiconductor device which is more appropriate for a high frequency operation.

### Third Embodiment

A semiconductor device according to the present embodiment is different from the semiconductor devices according to the first and second embodiments in that a sixth silicon carbide region 10c of a p⁺-type is provided instead of the n-type drain region (fifth silicon carbide region) 10a. Here, description of the contents which overlap those of the first and second embodiments will be omitted.

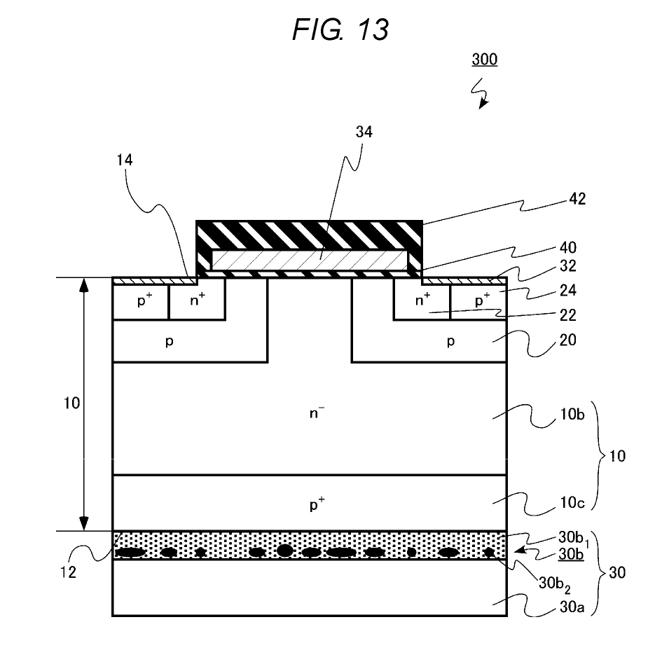

FIG. 13 is a schematic sectional view of the semiconductor device according to the present embodiment.

In a semiconductor device 300 according to the present embodiment, the sixth silicon carbide region 10c is a silicon carbide layer of p⁺-type. The sixth silicon carbide region 10c contains aluminum (Al) with impurity concentration, for example, higher than or equal to 1×10¹⁸ atoms/cm³ and lower than or equal to 1×10²⁰ atoms/cm³, as p-type impurity. The sixth silicon carbide region 10c functions as a collector region of the semiconductor device 300. The semiconductor device 300 according to the present embodiment is an insulated gate bipolar transistor (IGBT).

The second electrode 30 functions as a collector electrode. In addition, the third electrode 32 functions as an emitter electrode.

According to the semiconductor device 300 according to the present embodiment, it is possible to provide a semiconductor device which improves reliability by decreasing the likelihood of film separation of the second electrode (collector electrode).

### Fourth Embodiment

A semiconductor device according to the present embodiment includes a silicon carbide layer which has a first surface, and a second surface that is provided on a side opposite to the first surface; a first silicon carbide region of a first conductivity type which is provided in the silicon carbide layer; a second silicon carbide region of a second conductivity type which is provided in the silicon carbide layer on the first silicon carbide region, and a portion of which is provided on the first surface; a first electrode which is provided on the first surface and contains a metal, silicon, and carbon; a second electrode which is provided on the second surface, contains the metal, the silicon, and the carbon, and whose carbon concentration is lower than carbon concentration of the first electrode; and a third silicon carbide region of a first conductivity type which is provided in the silicon carbide layer between the first silicon carbide region and the second electrode, and a portion of which is provided on the second surface. The semiconductor device according to the present embodiment is a PIN type diode. Here, description of the contents which overlap those of the first to third embodiments will be omitted.

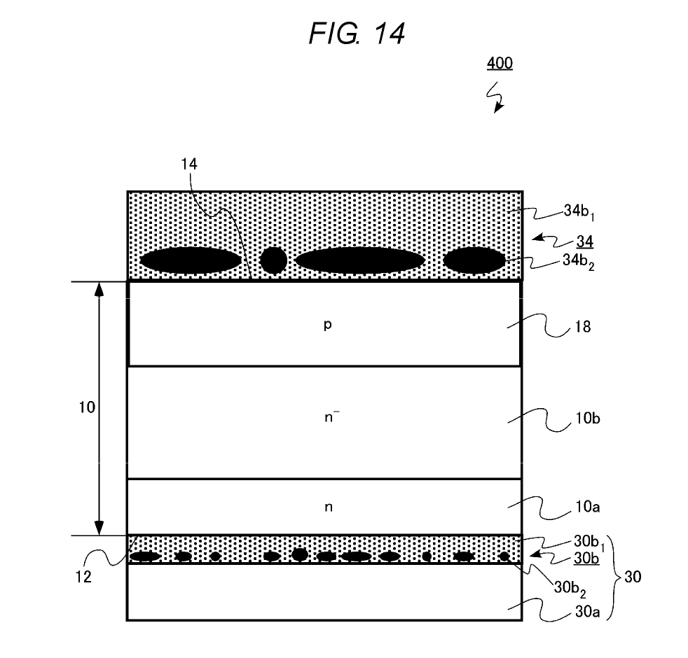

FIG. 14 is a schematic sectional view of the semiconductor device according to the present embodiment.

The third electrode 32 according to the first to third embodiments corresponds to the first electrode 34 according to the present embodiment. The second electrode 30 functions as a cathode electrode, and the first electrode 34 functions as an anode electrode. A third silicon carbide region 10a functions as an n-type emitter layer, the first silicon carbide region 10b functions as an n⁻-type base layer, and a fourth silicon carbide layer 18 functions as a p-type emitter layer.

According to the semiconductor device according to the present embodiment, it is possible to provide a semiconductor device which improves reliability by decreasing the likelihood of film separation of the second electrode (cathode electrode).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device, comprising:
a silicon carbide layer having a first surface and a second surface on a side opposite to the first surface;
a first insulating film on the first surface;
a first electrode on the first insulating film;
a first silicon carbide region of a first conductivity type in the silicon carbide layer;
a second silicon carbide region of a second conductivity type in the first silicon carbide region, a portion of which is at the first surface;
a third silicon carbide region of the first conductivity type in the second silicon carbide region, a portion of which is at the first surface;
a second electrode on the second surface, the second electrode including:
a first layer that is a metal silicide, and
a second layer between the first layer and the second surface and including a first phase region that is a metal silicide including carbon and a second phase region including carbon, the second phase region being disposed within the second layer closer to first layer than to the silicon carbide layer, a carbon concentration of the first phase region being higher than a carbon concentration of the first layer; and
a third electrode in contact with the third silicon carbide region and containing metal, silicon, and carbon, and having a carbon concentration that is higher than a carbon concentration of the second electrode.

2. The device according to claim 1, wherein the carbon concentration of the third electrode is higher than or equal to 1×10¹⁸ atoms/cm³.

3. The device according to claim 2, wherein a thickness of the second electrode is greater than a thickness of the third electrode.

4. (canceled)

5. The device according to claim 1, wherein the metal silicide of the first layer is nickel silicide, and the metal silicide of the first phase region is nickel silicide.

6. The device according to claim 1, further comprising:
a fourth silicon carbide region of the second conductivity type in the second silicon carbide region, which is electrically coupled to the third electrode, and has an impurity concentration higher than an impurity concentration of the second silicon carbide region.

7. The device according to claim 6, further comprising:
a fifth silicon carbide region of the first conductivity type in the silicon carbide layer and between the first silicon carbide region and the second electrode.

8. The device according to claim 1, further comprising:
a fifth silicon carbide region of the second conductivity type in the silicon carbide layer and between the first silicon carbide region and the second electrode.

9. The device according to claim 1, wherein the first electrode is a metal electrode.

10. The device according to claim 1, wherein the first electrode is a metal silicide electrode.

11. A semiconductor device, comprising:
a silicon carbide layer having a first surface and a second surface on a side opposite to the first surface;
a first silicon carbide region of a first conductivity type in the silicon carbide layer;
a second silicon carbide region of a second conductivity type in the silicon carbide layer on the first silicon carbide region, a portion of which is at the first surface;
a first electrode on the first surface, which contains metal, silicon, and carbon;
a second electrode on the second surface and comprising metal, silicon, and carbon, and having a carbon concentration lower than a carbon concentration of the first electrode, the second electrode including:
a first layer that is a metal silicide, and
a second layer between the first layer and the second surface and including a first phase region that is a metal silicide including carbon and a second phase region including carbon, the second phase region being disposed within the second layer closer to first layer than to the silicon carbide layer, a carbon concentration of the first phase region being higher than a carbon concentration of the first layer; and
a third silicon carbide region of the first conductivity type in the silicon carbide layer between the first silicon carbide region and the second electrode.

12. The device according to claim 11, further comprising:
a fourth silicon carbide region of the first conductivity type in the silicon carbide layer on the second silicon carbide region, a portion of which is at the first surface and in contact with the first electrode.

13. The device according to claim 12, further comprising:
a fifth silicon carbide region of the second conductivity type in the silicon carbide layer on the second silicon carbide region, a portion of which is at the first surface and in contact with the first electrode.

14. The device according to claim 13, further comprising:
a third electrode directly above portions of the first, second, and fourth silicon carbide regions.

15. The device according to claim 14, further comprising:
a gate insulating layer between the third electrode and the portions of the first, second, and fourth silicon carbide regions.

16. The device according to claim 15, wherein the third electrode is a metal electrode.

17. The device according to claim 15, wherein the third electrode is a metal silicide electrode.

18. The device according to claim 14, wherein the portion of the second silicon carbide region underneath the third electrode surrounds the portion of the first silicon carbide region underneath the third electrode.

19. The device according to claim 11, wherein the first electrode is a source electrode of a metal oxide semiconductor field effect transistor and the second electrode is a drain electrode of the metal oxide semiconductor field effect transistor.

20. The device according to claim 11, wherein the first electrode is an emitter electrode of an insulated gate bipolar transistor and the second electrode is a collector electrode of the insulated gate bipolar transistor.

21. The device according to claim 1, wherein the second phase region contains carbon.
